(19) United States
(12) Patent Application Publication
(10) Pub. No.: US 2026/0040708 A1
(43) Pub. Date: Feb. 5, 2026

(54) IMAGE SENSING DEVICE AND IMAGING DEVICE INCLUDING THE SAME

(71) Applicant: SK hynix Inc., Icheon-si (KR)

(72) Inventors: Hyo Jun KWON, Icheon-si (KR); Sung Ho CHOI, Icheon-si (KR)

(21) Appl. No.: 19/025,639

(22) Filed: Jan. 16, 2025

(30) Foreign Application Priority Data
Jul. 31, 2024 (KR) 10-2024-0101403

(51) Int. Cl. H10F 39/00; H04N 23/81; H04N 25/13; H04N 25/703; H10F 39/18

(52) U.S. Cl. CPC H10F 39/807; H04N 23/81; H04N 25/135; H04N 25/703; H10F 39/182; H10F 39/8023; H10F 39/805; H10F 39/8053; H10F 39/8057

(57) ABSTRACT

Disclosed is an imaging device, including: an image sensing device including: an effective pixel region in which a first pixel group including active pixels configured to convert incident light into an electric signal to generate image pixel signals; and a second pixel group including the active pixels and light-shielded pixels into which introduction of the incident light is blocked are disposed; and an image signal processor configured to control the image sensing device.

### CROSS-REFERENCE TO RELATED APPLICATION(S)

This patent document claims the priority and benefits of Korean Patent Application No. 10-2024-0101403, filed Jul. 31, 2024, the entire contents of which is incorporated herein for all purposes by this reference.

### TECHNICAL FIELD

The present disclosure relates to an image sensing device and an imaging device including the same.

### BACKGROUND

Recently, with the development of information and communication technologies and the digitalization of image information, an increasing number of electrical devices, such as a digital camera, a camcorder, a mobile phone, a personal communication system (PCS), a game machine, security camera and a medical micro camera, are now equipped with image sensors. In general, the image sensor may include a pixel region which includes a photodiode and a peripheral circuit region. A unit pixel may include a photodiode and a transfer transistor. The transfer transistor may be disposed between the photodiode and a floating diffusion region and may transfer charges generated by the photodiode to the floating diffusion region.

### SUMMARY

Some implementations of the disclosed technology provide an image sensing device with an improved color mixing issue of the light between neighboring pixel regions through a configuration having a first groove in which a first trench portion is disposed and configured to completely pass through a photodiode.

Some implementations of the disclosed technology provide an image sensing device capable of compensating a black level of an active pixel through inclusion of a light-shieled pixel.

Some implementations of the disclosed technology provide an image sensing device with an improved light introduction of a light-shieled pixel by additionally disposing a blue color filter in a light-shielded pixel on a light-shielding layer to prevent light with a longer wavelength from reaching the light-shielding layer.

Some implementations of the disclosed technology provide an image sensing device with an improved resolution by allowing a light-shieled pixel to be disposed in an effective pixel region, and to be dividedly disposed per region of an effective pixel region.

Some implementations of the disclosed technology provide an image sensing device capable of generating high quality images through dark shading compensation by allowing a light-shielded pixel to be disposed in an effective pixel region and to be dividedly disposed per region of an effective pixel region.

Some implementations of the disclosed technology provide an imaging device with an improved color mixing issue of the light between neighboring pixel regions through a configuration having a first groove in which a first trench portion is disposed and configured to completely pass through a photodiode.

Some implementations of the disclosed technology provide an imaging device capable of compensating a black level of an active pixel through inclusion of a light-shieled pixel.

Some implementations of the disclosed technology provide an imaging device with an improved light introduction of a light-shieled pixel by additionally disposing a blue color filter in a light-shielded pixel on a light-shielding layer to prevent light with a longer wavelength from reaching the light-shielding layer.

Some implementations of the disclosed technology provide an imaging device with an improved resolution by allowing a light-shieled pixel to be disposed in an effective pixel region, and to be dividedly disposed per region of an effective pixel region.

Some implementations of the disclosed technology provide an imaging device capable of generating high quality images through dark shading compensation by allowing a light-shielded pixel to be disposed in an effective pixel region and to be dividedly disposed per region of an effective pixel region.

In one aspect, an imaging device is provided to include: an image sensing device including a pixel array that includes an image pixel region; and an image signal processor in communication with the image sensing device and configured to control the image sensing device, wherein the image pixel region includes 1) a first pixel group comprising first active pixels and 2) a second pixel group comprising second active pixels and light-shielded pixels into which introduction of incident light is blocked, each of the first active pixels and the second active pixels configured to convert incident light into an electric signal to generate image pixel signals.

In another aspect, an imaging sensing device is provided to include: an image pixel region including a first pixel group comprising first active pixels and a second pixel group comprising second active pixels, each of the first active pixels and the second active pixels configured to convert incident light into an electric signal to generate image pixel signals; wherein the second pixel group further comprising light-shielded pixels into which introduction of the incident light is blocked.

According to the embodiments, the color mixing issue of the light between neighboring pixel regions can be improved because a first groove in which a first trench portion is disposed completely passes through a photodiode.

In some embodiments, a black level of an active pixel can be compensated through inclusion of a light-shieled pixel.

In some embodiments, light introduction of a light-shieled pixel can be improved by additionally disposing a blue color filter in a light-shielded pixel on a light-shielding layer to prevent light with a longer wavelength from reaching the light-shielding layer.

In some embodiments, the resolution can be improved by allowing a light-shieled pixel to be disposed in an effective pixel region, and to be dividedly disposed per region of an effective pixel region.

In some embodiments, high quality images can be generated through dark shading compensation by allowing a light-shielded pixel to be disposed in an effective pixel region and to be dividedly disposed per region of an effective pixel region.

### BRIEF DESCRIPTION OF THE DRAWINGS

FIG. 1 is a block diagram illustrating an imaging system based on some implementations of the disclosed technology.

FIG. 2 is a block diagram illustrating an image sensing device of FIG. 1 based on some implementations of the disclosed technology.

FIG. 3 is a plan view illustrating a pixel array based on some implementations of the disclosed technology.

FIG. 4 is a plan view illustrating a second pixel group of an effective pixel region of FIG. 3 based on some implementations of the disclosed technology.

FIG. 5 is a cross-sectional view taken along section line A-A′ of FIG. 4.

FIG. 6 is a flowchart illustrating operations of image output and correction based on some implementations of the disclosed technology.

FIG. 7 is a plan view illustrating an output image based on some implementations of the disclosed technology.

FIG. 8 is a cross-sectional view of a pixel array based on some implementations of the disclosed technology.

FIG. 9 is a cross-sectional view of a pixel array based on some implementations of the disclosed technology.

FIG. 10 is a cross-sectional view of a pixel array based on some implementations of the disclosed technology.

FIG. 11 is a cross-sectional view of a pixel array based on some implementations of the disclosed technology.

FIG. 12 is a cross-sectional view of a pixel array based on some implementations of the disclosed technology.

FIG. 13 is a plan view illustrating a second pixel group of an effective pixel region based on some implementations of the disclosed technology.

FIG. 14 is a cross-sectional view taken along section line B-B′ of FIG. 13.

FIG. 15 is a plan view illustrating a second pixel group of an effective pixel region based on some implementations of the disclosed technology.

FIG. 16 is a cross-sectional view taken along section line C-C′ of FIG. 15.

FIG. 17 is a plan view illustrating a second pixel group of an effective pixel region based on some implementations of the disclosed technology.

FIG. 18 is a plan view illustrating a second pixel group of an effective pixel region based on some implementations of the disclosed technology.

### DETAILED DESCRIPTION

Hereinafter, example embodiments will be described with reference to the accompanying drawings.

Like reference numerals refer to like elements throughout. Additionally, in the drawings, the thicknesses, proportions, and dimensions of components may be exaggerated for the purpose of effective explanation.

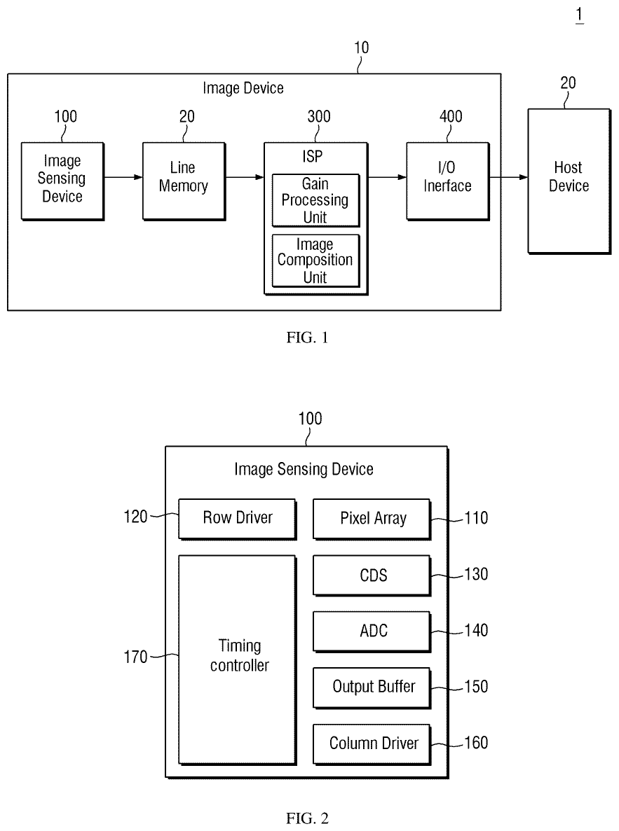

FIG. 1 is a block diagram illustrating an imaging system based on an embodiment of the disclosed technology. FIG. 2 is a block diagram illustrating an example of an image sensing device illustrated in FIG. 1.

Referring to FIG. 1, in some embodiments, the imaging system 1 may refer to a device such as a digital still camera for capturing still images, a digital video camera for recording videos, or a device for detecting a motion. For example, the imaging device 10 may be implemented as a Digital Single Lens Reflex (DSLR) camera, a mirrorless camera, or a smartphone, and others, but is not limited thereto. The imaging device 10 may include a device including a lens and an image sensor to capture a target object and create an image of the target object.

The imaging system 1 may include an imaging device 10 and a host device 20.

The imaging device 10 may include an image sensing device 100, a line memory 200, an image signal processor (ISP) 300, and an input/output (I/O) interface 400.

The image sensing device 100 may be a complementary metal oxide semiconductor image sensor (CMOS image sensor or CIS) for converting an optical signal into an electrical signal. The image sensing device 100 may control overall operations such as on/off operations, operation mode, operation timing, sensitivity, etc. by the ISP 300. The image sensing device 100 may transmit, to the line memory 200, with image data obtained by converting the optical signal into the electrical signal based on the control of the ISP 300.

Referring to FIG. 2, the image sensing device 100 may include a pixel array 110, a row driver 120, a correlated double sampler (CDS) 130, an analog-digital converter (ADC) 140, an output buffer 150, a column driver 160, and a timing controller 170. The components of the image sensing device 100 illustrated in FIG. 2 are discussed by way of example only, and at least some components may be added or omitted.

The pixel array 110 may include a plurality of imaging pixels arranged in a plurality of rows and a plurality of columns. In an embodiment, the plurality of imaging pixels can be arranged in a two dimensional pixel array including rows and columns. In another example, the plurality of imaging pixels can be arranged in a three dimensional pixel array. The plurality of imaging pixels may convert an optical signal into an electrical signal on a unit pixel basis or a pixel group basis, where the imaging pixels in a pixel group share at least certain internal circuitry. The pixel array 110 may receive pixel control signals, including a row selection signal, a pixel reset signal and a transmission signal, from the row driver 120. Upon receiving the pixel control signals, corresponding pixels in the pixel array 110 may be activated to perform the operations corresponding to the row selection signal, the pixel reset signal, and the transmission signal. Each of the imaging pixels may generate photocharges corresponding to the intensity of incident light (or luminous intensity), may generate an electrical signal corresponding to the amount of photocharges, thereby sensing the incident light. For convenience of description, the imaging pixel may also be referred to as a pixel.

The row driver 120 may activate the pixel array 110 to perform certain operations on the imaging pixels in the corresponding row based on commands and control signals provided by the timing controller 170. In an embodiment, the row driver 120 may select at least one pixel arranged in at least one row of the pixel array 110. The row driver 120 may generate a row selection signal to select at least one row among the plurality of rows. The row driver 120 may sequentially enable the pixel reset signal and the transmission signal for the pixels corresponding to at least one selected row. Thus, a reference signal and an image signal, which are analog signals generated by each of the pixels of the selected row, may be sequentially transferred to the CDS 130. The reference signal may be an electrical signal that is provided to the CDS 130 when a sensing node of a pixel (e.g., floating diffusion node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be referred to as a pixel signal.

The image sensing device 100 may use the correlated double sampling (CDS) to remove undesired offset values of pixels known as the fixed pattern noise by sampling a pixel signal twice to remove the difference between these two samples. In an embodiment, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

The CDS 130 may transfer the reference signal and the image signal of each of the columns as a correlate double sampling signal to the ADC 140 based on control signals from the timing controller 170.

The ADC 140 may convert analog CDS signals output from the CDS 130 with respect to each column into digital signals, and output image data. In an embodiment, the ADC 140 may convert the correlate double sampling signal generated by the CDS 130 for each of the columns into a digital signal, and output the digital signal.

The ADC 140 may include a plurality of column counters. Each column of the pixel array 110 is coupled to a column counter, and image data can be generated by converting the correlate double sampling signals corresponding to each column into digital signals using the column counter. In another embodiment of the disclosed technology, the ADC 140 may include a global counter to convert the correlate double sampling signals corresponding to each of the columns into digital signals using a global code provided from the global counter.

The output buffer 150 may temporarily hold the column-based image data provided from the ADC 140 to output the image data. The output buffer 150 may temporarily store image data output from the ADC 140 based on the control signal of the timing controller 170. The output buffer 150 may serve as an interface to compensate for data rate differences (or data processing speed differences) between the image sensing device 100 and other devices.

The column driver 160 may select a column of the output buffer 150 based on a control signal from the timing controller 170, and sequentially output the image data, which are temporarily stored in the selected column of the output buffer 150. In an embodiment, the column driver 160 may receive an address signal from the timing controller 170, generate a column selection signal based on the address signal and select a column of the output buffer 150, thereby outputting the image data from the selected column of the output buffer 150.

The timing controller 170 may control at least one among the row driver 120, the CDS 130, the ADC 140, the output buffer 150 and the column driver 160.

The timing controller 170 may provide at least one among the row driver 120, the CDS 130, the ADC 140, the output buffer 150 and the column driver 160 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

Referring back to FIG. 1, the line memory 200 may include a volatile memory (e.g., DRAM, SRAM, etc.) and/or a non-volatile memory (e.g., a flash memory). The line memory 200 may have a capacity capable of storing image data corresponding to a predetermined number of lines. In this case, the line may refer to a row of the pixel array 110, and the predetermined number of lines may be less than a total number of rows of the pixel array 110. Therefore, the line memory 200 may be a line memory capable of storing image data corresponding to some rows (or some lines) of the pixel array 110, rather than a frame memory capable of storing image data corresponding to a frame captured once by the pixel array 110. In another embodiment, the line memory 200 may also be replaced with a frame memory.

The line memory 200 may receive image data from the image sensing device 100, may store the received image data, and may transmit the stored image data to the ISP 300 based on the control of the ISP 300.

The ISP 300 may perform image processing of the image data stored in the line memory 200. The ISP 300 may reduce noise of image data, and may perform various kinds of image signal processing such as gamma correction, color filter array interpolation, color matrix, color correction, color enhancement, lens distortion correction, etc. for image-quality improvement of the image data. In addition, the ISP 300 may compress image data that has been created by execution of image signal processing for image-quality improvement, such that the ISP 300 can create an image file using the compressed image data. Alternatively, the ISP 300 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or others can be used. In addition, in the case of using moving images, a plurality of frames can be compressed according to Moving Picture Experts Group (MPEG) standards such that moving image files can be created. For example, the image files may be created according to Exchangeable image file format (Exif) standards.

In order to generate the HDR image, the ISP 300 may include a gain processing unit 310, and an image composition unit 320.

The gain processing unit 310 may determine a gain to be calculated with (to be multiplied by) image data. The gain processing unit 310 may determine a gain according to a difference in the conversion gain between the high conversion gain (HCG) mode and the low conversion gain (LCG) mode, and may provide the determined gain to the image composition unit 320. The gain may be experimentally determined in advance according to the difference in the conversion gain, and may be stored in the gain processing unit 310. In an embodiment, the gain processing unit 310 may store the experimentally determined gain in a table according to a size of the image data, such that the gain processing unit 310 may acquire a necessary gain corresponding to the image data by referring to content stored in the table.

Each pixel of the pixel array 110 may operate in one mode among the HCG mode and LCG mode, and the mode of each pixel may be determined according to the intensity (or illuminance) of light that is incident on each pixel. The HCG mode means a mode in which the pixel has a relatively greater conversion gain, and the LCG mode means a mode in which the pixel has relatively smaller conversion gain. At this time, the conversion gain may mean a ratio of a voltage level of the pixel signal, of which the photocharges are converted, to the amount of photocharges generated in the pixel. The amount of photocharges generated in the pixel is proportionate to illuminance with respect to each pixel, and thus, the HCG mode may mean a mode having a relatively greater change of the pixel signal according to the change of the illuminance, and the LCG mode may mean a mode having a relatively smaller change of the pixel signal according to the change of the illuminance.

In the HCG mode and the LCG mode, slopes of the pixel signal with respect to the illuminance are different from each other. The gain may be a correction value to make a slope of the pixel signal (or image data) with respect to the illuminance of the pixel operating in the HCG mode, and a slope of the pixel signal (or image data) with respect to the illuminance of the pixel operating in the LCG mode be equal to each other.

The image composition unit 320 may synthesize HDR image corresponding to a high dynamic range by using the image data of the pixel operating in the HCG mode and/or the image data of the pixel operating in the LCG mode.

In an embodiment, the image composition unit 320 may perform a calculation based on the gain provided from the gain processing unit 310, on the image data of the pixel operating in the HCG mode and/or the image data of the other pixel operating in the LCG mode, and may allow the calculated image data to be formed as the HDR image.

The ISP 300 may transmit image data (e.g., HDR image data) obtained by such image signal processing to the I/O interface 400.

In another embodiment, the gain processing unit 310 and the image composition unit 320, which are used to generate an HDR image, may be included in the image sensing device 100 instead of the ISP 300.

The I/O interface 400 may perform a communication with the host device 20, and may transmit the image signal processed (ISP) image data to the host device 20. According to the embodiment, the I/O interface 400 may be implemented as, for example, a mobile industry processor interface (MIPI). In the implementations, the input/output interface 400 can include various interfaces without being limited to the MIPI.

The host device 20 may be a processor (e.g., an application processor) for processing the ISP image data received from the imaging device 10, a memory (e.g., a non-volatile memory) for storing the ISP image data, or a display device (e.g., a liquid crystal display (LCD)) for visually displaying the ISP image data.

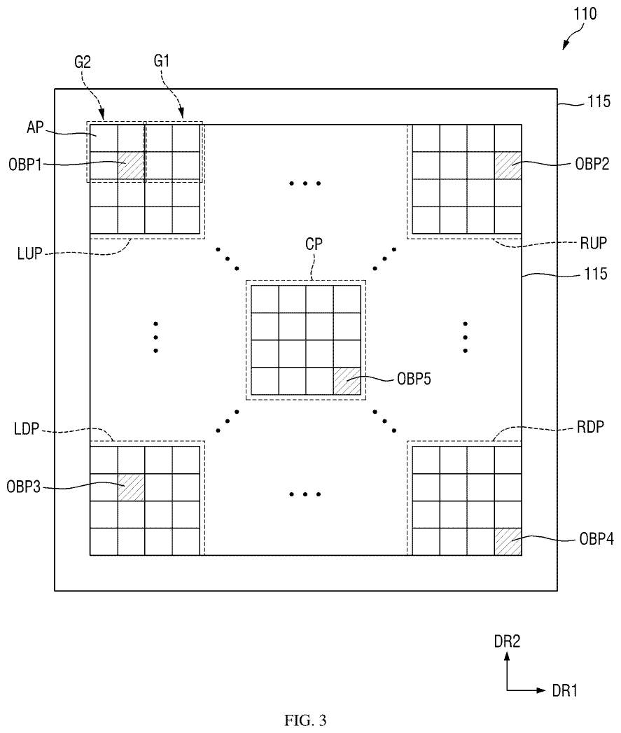

FIG. 3 is a plan view illustrating an example of a pixel array as shown in FIG. 2.

In the example as shown in FIG. 3, the pixel array 110 may include an effective pixel region 111 and a dummy pixel region 115 around the effective pixel region 111. As discussed below, the effective pixel region may include position pixel groups, each including at least one active pixels configured to generate electrical signal to form an image through photo electric conversion of incident light received from outside and the dummy pixel region may include dummy pixels. The dummy pixel region 115 may be positioned outside of the effective pixel region 111 to be near to the effective pixel region 111. The dummy pixel region 115 may include a plurality of dummy pixels having the same structure as that of active pixels, and the dummy pixels may be continuously disposed in a row direction (for example, a first direction DR1), and a column direction (for example, a second direction DR2), for example. The dummy pixels included in the dummy pixel region may be distinguished from the effective pixels in the effective pixel region in terms of the operations as not being directly utilized for the image formation. The dummy pixels are designed and operated to compensate for undesired characteristics of the image sensing device and improve overall imaging operation of the image sensing device. The dummy pixels may produce dummy pixel signals without being exposed or receiving the incident light.

The effective pixel region 111 may include a plurality of position pixel groups. For example, the effective pixel region 111 may include a first position pixel group LUP, a second position pixel group RUP, a third position pixel group LDP, a fourth position pixel group RDP, and a fifth position pixel group CP. For example, the first position pixel group LUP may be positioned at a first position, and the first position may be an upper-left side of the effective pixel region 111. The second position pixel group RUP may be positioned at a second position, and the second position may be an upper-right side of the effective pixel region 111. The third position pixel group LDP may be positioned at a third position, and the third position may be a lower-left side of the effective pixel region 111. The fourth position pixel group RDP may be positioned at a fourth position, and the fourth position may be a lower-right side of the effective pixel region 111. The fifth position pixel group CP may be positioned at a fifth position, and the fifth position may be or correspond to a center of the effective pixel region 111. In the example as shown in FIG. 3, each of the position pixel groups LUP, RUP, LDP, RDP, and CP is configured with three first pixel groups G1, and one second pixel group G2. However, other implementations are also possible. For example, each of the position pixel groups LUP, RUP, LDP, RDP, and CP may include four or more first pixel groups G1, and two or more second pixel groups G2.

In the example as shown in FIG. 3, the effective pixel region 111 is illustrated to include the first position pixel group LUP, the second position pixel group RUP, the third position pixel group LDP, the fourth position pixel group RDP, and the fifth position pixel group CP. However, other implementations are also possible. For example, in some implementations, the effective pixel region 111 may include position pixel groups disposed at more than five positions.

In the example as shown in FIG. 3, the first pixel group G1 refers to a pixel group including the active pixels AP only, and the second pixel group G2 refers to a pixel group including the active pixels AP and light-shielded pixels OBP1 to OBP5. In the present disclosure, the light-shielded pixel may be referred to as a black pixel. The black pixel may be shielded from light that is incident upon a surface of the imaging system 1 and can be used, for example, for noise correction, and so on. The active pixel is configured to convert incident light into an electric signal to generate an image pixel signal. For example, the second pixel group G2 of the first position pixel group LUP may include a first light-shielded pixel OBP1, the second pixel group G2 of the second position pixel group RUP may include a second light-shielded pixel OBP2, the second pixel group G2 of the third position pixel group LDP may include a third light-shielded pixel OBP3, the second pixel group G2 of the fourth position pixel group RDP may include a fourth light-shielded pixel OBP4, and the second pixel group G2 of the fifth position pixel group CP may include a fifth light-shielded pixel OBP5. In the example as shown in FIG. 3, each of the position pixel groups LUP, RUP, LDP, RDP, and CP includes only one light-shielded pixel among OBP1 to OBP5, but other implementations are also possible. For example, in some implementations, each of the position pixel groups LUP, RUP, LDP, RDP, and CP may include two or more light-shielded pixels among OBP1 to OBP5.

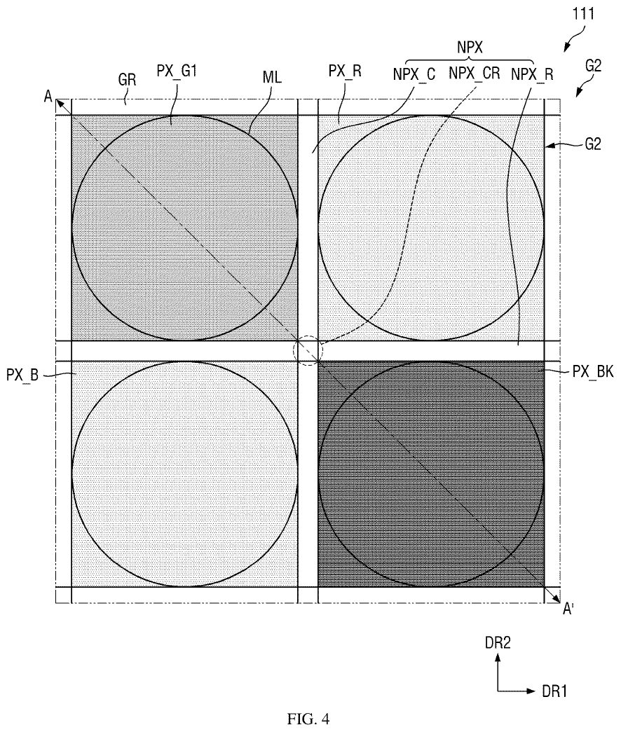

FIG. 4 is a plan view illustrating an example of a second pixel group of the effective pixel region as shown in FIG. 3.

Referring to FIG. 4, the second pixel group G2 of the effective pixel region 111 according to the embodiment may include a plurality of active pixels and one light-shielded pixel. The plurality of active pixels may include a first pixel, a second pixel, and a third pixel. Though not illustrated, a first pixel group G1 of the effective pixel region 111 may include the first pixel to the fourth pixel. The fourth pixel may be a pixel having the same color as that of the first pixel. In case of a second pixel group G2, a light-shielded pixel may be disposed in a region in which the fourth pixel of the first pixel group G1 is positioned. Referring back to FIG. 4, each of the pixels may include pixel regions PX_G1, PX_R, PX_B, and PX_BK and a non-pixel region NPX. The first pixel may be a green pixel which receives green light, the second pixel may be a red pixel which receives red light, the third pixel may be a blue pixel which receives blue light, and the fourth pixel may be a green pixel which receives green light. The light-shielded pixel may be a pixel shielded from the incident light. The plurality of pixels may be repeatedly disposed along a first direction DR1 and a second direction DR2, but are not limited thereto. Considering a peak wavelength range of the light to be received, a color filter may be disposed in each of the plurality of pixels. For example, a green color filter is disposed in the first pixel, a red color filter is disposed in the second pixel, and a blue color filter is disposed in the third pixel. A black color filter is disposed in the light-shielded pixel.

In some embodiments, the plurality of pixels may further include a fifth pixel which receives white light, but the embodiments of the present disclosure are not limited thereto.

The first pixel includes a first pixel region PX_G1 and a non-pixel region NPX surrounding the first pixel region PX_G1, a second pixel includes a second pixel region PX_R and a non-pixel region NPX surrounding the second pixel region PX_R, a third pixel includes a third pixel region PX_B and a non-pixel region NPX surrounding the third pixel region PX_B, and the light-shielded pixel includes a light-shielded pixel region PX_BK and a non-pixel region NPX surrounding the light-shielded pixel region PX_BK.

The non-pixel region NPX may be formed between neighboring pixels. For example, the non-pixel region NPX may be disposed in boundaries of each pixel.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The effective pixel region 111 according to the embodiment may further include a light concentrating pattern ML. The light concentrating pattern ML may be provided in plurality. The plurality of light concentrating patterns ML may be disposed in each of the pixels.

The effective pixel region 111 according to the embodiment may further include a grid portion. The grid portion may include a grid portion GR. The grid portion GR may include an air structure. In some embodiments, the effective pixel region 111 may further include a second grid portion including a metal material, or the grid portion GR may include a metal material, but the embodiment of the present disclosure is not limited thereto. For example, the second grid portion GR2 may include a metal material which absorbs light, and may include tungsten (W), but the embodiments of the present disclosure are not limited thereto.

For example, the grid portion GR may be disposed throughout the first non-pixel region NPX_R and the second non-pixel region NPX_C of the non-pixel region NPX, and the grid portion GR may not be disposed over the third non-pixel region NPX_CR. However, the embodiments of the present disclosure are not limited thereto, and the grid portion GR may be disposed over the third non-pixel region NPX_CR.

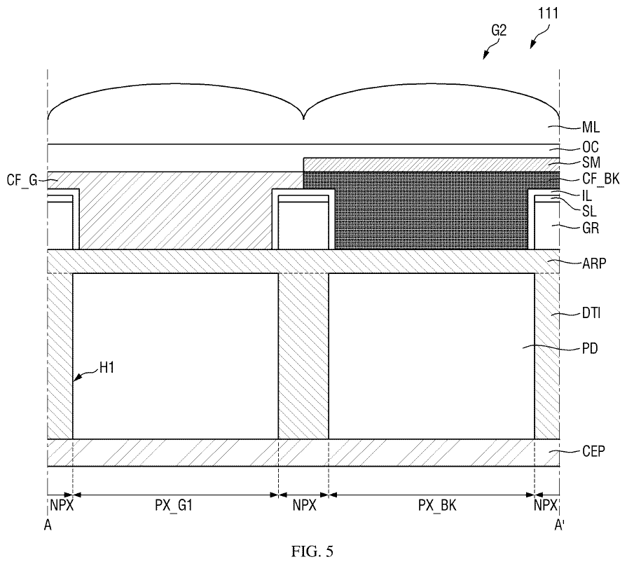

FIG. 5 is a cross-sectional view taken along section line A-A′ of FIG. 4.

In FIG. 5, cross-sectional views of the first pixel and the light-shielded pixel are illustrated. In some implementations, the effective pixel region 111 may include a circuitry CEP, a photodetector such as a photodiode PD on the circuitry CEP, a first trench portion DTI, an anti-reflection layer ARP on the photodiode PD, a grid portion GR on the anti-reflection layer ARP in the non-pixel region NPX, a stopper layer SL on the grid portion GR in the non-pixel region NPX, an insulation layer IL on the stopper layer SL and the anti-reflection layer ARP, color filters CF_G and CF_BK on the insulation layer IL, a light-shielding layer SM on the black color filter CF_BK, a planarization layer OC on the light-shielding layer SM and the color filters CF_G and CF_BK, and the light concentrating pattern ML on the planarization layer OC. While the photodiode PD is described as the example of the photodetector in the description below, other implementations are also possible as long as it is capable of producing an electrical signal in response to received light. For example, the photodetector can include a photo transistor, a photo gate, or other photosensitive circuitry capable of converting light into a pixel signal (e.g., a charge, a voltage or a current).

The circuitry CEP is disposed on a bottom surface of the photodiode PD, and may include transistors, a wiring layer, and an interlayer insulation layer. The transistors may include an overflow transistor, a transfer transistor, a reset transistor, a driving transistor, and a selection transistor, all of which are formed on the bottom surface of the photodiode PD.

The photodiode PD may include a single-crystalline silicon wafer or an epitaxially grown single-crystalline silicon layer. The photodiode PD may have a high refractive index. For example, the refractive index of the photodiode PD may be about 2.5 or more, but is not limited thereto. For example, the refractive index of the photodiode PD may be about 4 to 6, but is not limited thereto.

The photodiode PD may be formed by injecting P-type ions and N-type ions. The P-type ions may include boron (B) ions, and N-type ions may include phosphorous (P) ions and/or arsenic (As) ions. The photodiode PD serves to convert the optical signals into the electric signals by receiving the incident light. The photodiode PD may refer to only a portion which corresponds to the pixel regions PX_G1 and PX_BK, but is not limited thereto.

In the layer in which photodiode PD is disposed, a first groove H1 may be formed. The first groove H1 may be formed by indenting the photodiode PD in a thickness direction. The first groove H1 may be formed in the non-pixel region NPX, while the photodiode PD is disposed in the pixel region. For example, the first groove H1 may completely pass through the photodiode PD from an upper surface to a bottom surface thereof in a thickness direction. In the first groove H1, the first trench portion DTI may be formed. The first trench portion DT1 may be formed through a deep trench process. The first trench portion DT1 may completely fill in the first groove H1. In some embodiments, a second groove may be formed in the layer in which photodiode PD is disposed, and the number of the second grooves can be varied. For example, one, two, or three or more second grooves can be provided in the pixel regions PX_G1 and PX_BK. In the second groove, a second trench portion may be disposed, and the number of the second trench portions may be varied. For example, one, two, or three or more second trench portions may be provided in one pixel region PX_G1 and PX_BK. The first trench portion DTI and the second trench portion may include the same material. For example, the first trench portion DTI and the second trench portion may include an insulation material. For example, an example of the insulation material is hafnium oxide (HfO2), or silicon oxide (SiO2), but is not limited thereto. The refractive index of the first trench portion DTI may be, for example, about 1.4 to 2.0, but is not limited thereto. The first trench portion DTI serves to totally reflect light incident into the first trench portion DTI to the photodiode PD. The first trench portion DTI may improve a color mixing issue between neighboring pixels. The second trench portion serves to scatter light incident from the light concentrating pattern ML. The first trench portion DTI and the second trench portion may serve to increase a path of the light by totally reflecting the light to the photodiode PD or scattering the light, respectively. Because of this, the trench portion may serve to improve a quantum efficiency of the photodiode PD.

The anti-reflection layer ARP may be disposed on the photodiode PD and the first trench portion DTI. The anti-reflection layer ARP may be in direct contact with the photodiode PD and the first trench portion DTI. The anti-reflection layer ARP may include a material which is the same as the material of the first trench portion DTI. The anti-reflection layer ARP may be formed in the same manufacture process as the manufacture process of the first trench portion DTI, and may be integrally connected with the first trench portion DTI. The anti-reflection layer ARP may serve to prevent the light incident into the light concentrating pattern ML from being totally reflected in the photodiode PD. To this end, the anti-reflection layer ARP may have a refractive index between a refractive index of the color filters CF_G and CF_BK and a refractive index of the photodiode PD, but is not limited thereto. For example, the refractive index of the anti-reflection layer ARP may be about 1.4 to 2.0, but is not limited thereto. The anti-reflection layer ARP may be disposed throughout the pixel regions PX_G1 and PX_BK, and the non-pixel region NPX.

The grid portion GR may be disposed on the anti-reflection layer ARP. The grid portion GR may be disposed in the non-pixel region NPX. The grid portion GR may include a low refractive layer that allows light to pass through whit minimal refraction. For example, the grid portion GR may include a low refractive insulation material, or an air structure (e.g., a structure including air). In the embodiment, the first grid portion GR1 may include an air structure. The first grid portion GR1 may be disposed in the non-pixel region NPX, and may serve to totally reflect the light incident into the grid portion GR. The grid portion GR may prevent color mixing of the light between the neighboring pixel regions PX_G1 and PX_BK.

In some embodiments, the grid portion GR may be formed of a metal. For example, the metal may absorb light incident into the grid portion GR. For example, the metal may be tungsten (W), but the embodiments of the present disclosure are not limited thereto.

On the grid portion GR in the non-pixel region NPX, the stopper layer SL may be disposed. The stopper layer SL is disposed on a sacrificial layer which will be sacrificed in the manufacture process and may serve as an etching stopper with respect to an etchant or an etching gas in the course of removing the sacrificial layer in the pixel regions PX_G1 and PX_BK. For example, the stopper layer SL may include silicon nitride (SiNx), but the embodiments of the present disclosure are not limited thereto.

The insulation layer IL may be disposed on the stopper layer SL and the grid portion GR. The insulation layer IL may include an insulation material. For example, the insulation layer IL may include silicon oxide (SiO2), but is not limited thereto. The insulation layer IL may directly contact a side surface of the grid portion GR, a side surface of the stopper layer SL, and an upper surface of the stopper layer SL. The insulation layer IL may expose an upper surface of the anti-reflection layer ARP in the pixel regions PX_G1 and PX_BK. However, the embodiments of the present disclosure are not limited thereto, the insulation layer IL may entirely cover the upper surface of the anti-reflection layer ARP in the pixel regions PX_G1 and PX_BK. The insulation layer IL is formed in a region in which the grid portion GR is to be formed in a process of forming the grid portion GR having the air structure. Oxygen is irradiated onto the insulation layer IL, and the irradiated oxygen passes through the insulation layer IL and oxidizes the sacrificial layer filling the region where the grid portion GR is to be formed. The oxidized sacrificial layer becomes carbon dioxide and is removed to form the grid portion GR having the air structure. Therefore, the insulation layer IL may be a multiporous layer.

The color filters CF_G and CF_BK may be disposed on the grid portion GR and the planarization layer OC. A green color filter CF_G may be disposed in the first pixel region PX_G1, and a black color filter CF_BK may be disposed in the light-shielded pixel region PX_BK. The green color filter CF_G may transmit the green light, and absorb or shield the light of other colors. The black color filter CF_BK may absorb or shield the light in all the wavelength ranges.

The light-shielding layer SM may be disposed on the black color filter CF_BK. The light-shielding layer SM may serve to shield or reflect the incident light. For example, the light-shielding layer SM may include a reflective metal which reflects the incident light. For example, the reflective metal may include aluminum (Al), but the embodiments of the present disclosure are not limited thereto. The light-shielding layer SM may be disposed only in the light-shielded pixel region PX_BK, but the embodiments of the present disclosure are not limited thereto, and the light-shielding layer SM may be disposed in the non-pixel region NPX neighboring to the light-shielded pixel region PX_BK.

The planarization layer may be disposed on the first color filter CF_G and the light-shielding layer SM. The light-shielding layer SM is disposed on the black color filter CF_BK, and is not disposed on the first color filter CF_G, and therefore, a stepped portion may be formed by the light-shielding layer SM in the first pixel region PX_G1 and the light-shielded pixel region PX_BK. However, according to the effective pixel region 111 according to the embodiment, the planarization layer OC is disposed on the light-shielding layer SM and the first color filter CF_G, and the stepped portion caused by the light-shielding layer SM can be planarized. The planarization layer OC may include an organic insulation material. However, the embodiments of the present disclosure are not limited thereto, and the planarization layer OC may include an inorganic insulation material.

The light concentrating pattern ML may be disposed on the planarization layer OC. The light concentrating pattern ML may serve to receive light incident from the outside into the pixel regions PX_G1 and PX_BK. To this end, the light concentrating pattern ML may have a shape of a convex lens that is convex upward, and may be formed of a material with a great difference in the refractive index compared to the refractive index of the external air. For example, the refractive index of the light concentrating pattern ML can be, but is not limited to, about 1.5 to about 1.7. The light concentrating pattern ML may be arranged continuously in the pixel regions PX_G1 and PX_BK and the non-pixel region NPX, as shown in FIG. 5, and may be formed such that an end of the convex lens shape is positioned in the center of the pixel regions PX_G1 and PX_BK, but is not limited to. For example, the light concentrating pattern ML may be disconnected in the non-pixel region NPX, in which case the plurality of the light concentrating patterns ML may be positioned in each of the pixel regions PX_G1 and PX_BK.

In some implementations, in the light-shielded pixel region PX_BK of the effective pixel region 111, the black color filter CF_BK which absorbs light in all colors and the light-shielding layer SM which reflects or absorbs the incident light are disposed, and thus, introduction of the incident light can be completely blocked in the light-shielded pixel region PX_BK.

In some embodiments, the black color filter CF_BK may include a plurality of layers. The black color filter CF_BK may include a stacked-layer structure of a red color filter, a green color filter, and a blue color filter. For example, a thickness of each of the red color filter, a green color filter, and a blue color filter may be different per wavelength, but the embodiments of the present disclosure are not limited thereto. As the same as the present disclosure, compared to a case in which a single layer of a black color filter is disposed, when the black color filter CF_BK includes the red color filter, the green color filter, and the blue color filter, there is an effect that the incident light can be more effectively blocked.

Hereinafter, a method for outputting and correcting an image of the imaging system 1 according to the embodiment will be described with reference to FIGS. 3 to 6.

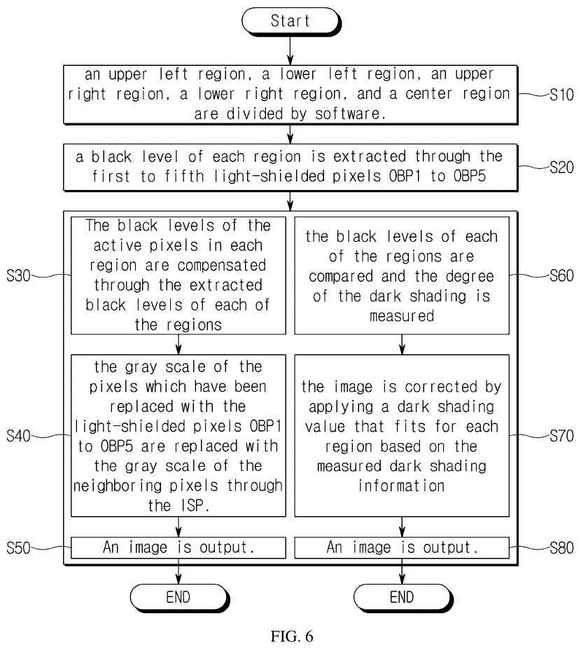

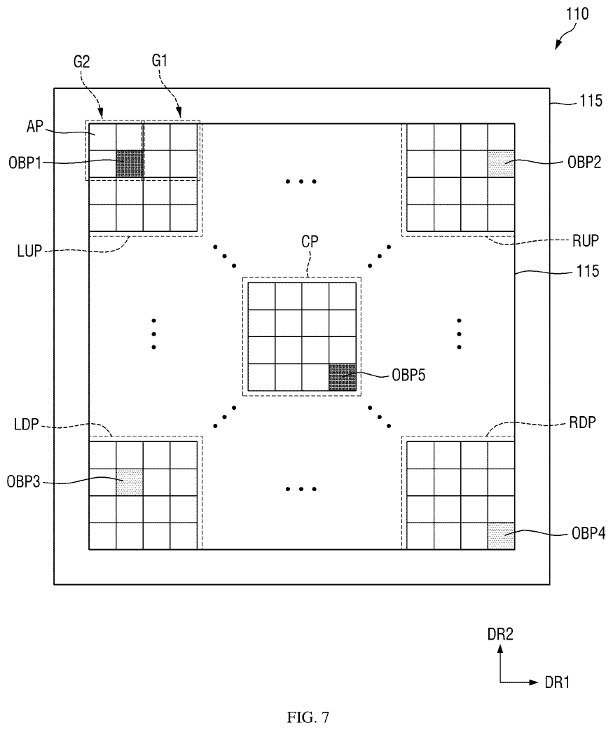

FIG. 6 is a flowchart illustrating operations performed by an imaging system, which include image output and correction operations based on an embodiment. FIG. 7 is a plan view illustrating an output image of FIG. 6.

With reference to FIGS. 3 to 6, an upper left region, a lower left region, an upper right region, a lower right region, and a center region are divided by software. (S10) For example, dividing the region into an upper left region, a lower left region, an upper right region, a lower right region, and a center region by software may be performed through an image signal processor ISP (refer to 300 in FIG. 1). For example, dividing the region into an upper left region, a lower left region, an upper right region, a lower right region, and a center region by software may mean dividing a plurality of positions in the effective pixel region 111 in FIG. 3 by software. For example, in FIG. 3, positions in the effective pixel region 111 are divided into five positions (an upper left region, a lower left region, an upper right region, a lower right region, and a center region). However, the embodiments of the present disclosure are not limited thereto, and the positions may be divided into six or more positions. That is, in the present operation S10, the image signal processor 300 may divide the effective pixel region 111 into a plurality of regions. Hereinafter, as an example, the image signal processor 300 divides the effective pixel region 111 into first to fifth positions, an upper left region, a lower left region, an upper right region, a lower right region, and a center region. In each of the first to fifth positions, the light-shielded pixels OBP1 to OBP5 are disposed. The light-shielded pixel disposed in each position may be two or more in number.

Thereafter, a black level of each region is extracted through the first to fifth light-shielded pixels OBP1 to OBP5 (S20). The black level in an image refers to the darkest shade of gray that can be represented in the image. Thus, the black level corresponds to a specific point within the greyscale range. The extracting of a black level of each region through the first to fifth light-shielded pixels OBP1 to OBP5 (S20) may be performed by the image signal processor 300. When the light-shieled pixels OBP1 to OBP5 positioned in each region are two or more in number, the black level extracted in this operation S20 may be an average black level of the light-shieled pixels OBP1 to OBP5 positioned in each region, but the embodiments of the present disclosure are not limited thereto. For example, the black level may have a unit of a digital number DN, and the digital number of a pure black level may be 64DN. For example, each of the active pixels AP and the light-shielded pixels OBP1 to OBP5 may have a black level. In some implementations, the black level and the gray scale may be used interchangeable. It is preferable that a black level of each of the light-shielded pixels OBP1 to OBP5 is a pure black level. When any incident light is not introduced into each of the light-shielded pixels OBP1 to OBP5, each of the light-shielded pixels OBP1 to OBP5 may have a pure black level. However, when a small amount of incident light is introduced into each of the light-shielded pixels OBP1 to OBP5, each of the light-shielded pixels OBP1 to OBP5 may have a black level higher than the pure black level.

After the extracting of a black level of each region through the first to fifth light-shielded pixels OBP1 to OBP5 (S20), the black levels of the active pixels in each region are compensated through the extracted black levels of each of the regions (S30). The compensating of the black levels of the active pixels (S30) may be performed by the image signal processor 300. For example, in the first position pixel group LUP illustrated in FIG. 3, when the black level (or gray scale) of the first light-shielded pixel OBP1 has 100DN, and the gray scale of one of the active pixels AP in the first position pixel group LUP has 300DN, the image signal processor 300 may compensate the black level by, for example, subtracting a difference between the black level of the first light-shieled pixel OBP1 and the pure black level (36DN) from the gray scale of any one active pixel. Therefore, the gray scale of the any one active pixel for which the black level is compensated may be 264DN.

Next, after compensating the black levels of the active pixels in each region based on the extracted black level of each region (S30), the gray scale of the active pixels which have been replaced with the light-shielded pixels OBP1 to OBP5 in each region are replaced with the gray scale of the neighboring pixels (S40). In the example, the active pixels replaced with the light-shielded pixels OBP1 to OBP5 may refer to fourth pixels included in each pixel group (e.g., 1^{st} position pixel group LUP, 2^{nd} position pixel group RUP, 3^{rd} position pixel group LDP, 4^{th} position pixel group RDP, and 5^{th} position pixel group CP) and having a same color to that of the first pixels in each pixel group. For example, as illustrated in FIGS. 3 and 4, in order to output an image, in the second pixel groups G2 in which the light-shielded pixels OBP1 to OBP5 are included, the gray scale of the active pixels (for example, the fourth pixel having the same color as the first pixel), which have been replaced with the light-shielded pixels OBP1 to OBP5, needs to be replaced with the gray scale of the neighboring pixels (for example, the first pixel in the first pixel group G1). In the operation of replacing the gray scale of the active pixels which have been replaced with the light-shielded pixels OBP1 to OBP5 in each region with the gray scale of the neighboring pixels (S40), “the gray scale” may have the same meaning as that of “the image pixel signal”. The operation of replacing the gray scale of the active pixels which have been replaced with the light-shielded pixels OBP1 to OBP5 in each region with the gray scale of the neighboring pixels (S40) may be performed through the image signal processor 300.

After replacing the gray scale of the active pixels which have been replaced with the light-shielded pixels OBP1 to OBP5 in each region with the gray scale of the neighboring pixels (S40), the image of which the black level is compensated and the gray scale is replaced is output (S50).

As illustrated in FIG. 6, a method for outputting and correcting an image of the imaging system 1 according to the embodiment compares the black levels of each of the regions and measures a degree of the dark shading (S60), after the extracting a black level of each region through the first to fifth light-shielded pixels OBP1 to OBP5 (S20). In the operation of comparing the black levels of each of the regions and measuring the degree of the dark shading (S60), the black levels of the light-shielded pixels OBP1 to OBP5 may be different from each other. A reason why the black levels of the light-shielded pixels OBP1 to OBP5 are different from each other is that the regions LUP, RUP, LDP, RDP, and CP in which the light-shielded pixels OBP1 to OBP5 are disposed are different from each other, and thus, the influence of the introduced incident light is different depending on the regions LUP, RUP, LDP, RDP, and CP. The operation of comparing the black levels of each of the regions and measuring the degree of the dark shading (S60) may be performed through the ISP 300. The view illustrated in FIG. 7 shows the degree of the dark shading measured, in case the black levels of the first light-shielded pixel OBP1 and the fifth light-shielded pixel OBP5 are lower than the black levels of the second light-shielded pixel OBP2 to the fourth light-shielded pixel OBP4.

Next, the image is corrected by applying a dark shading value that fits for each region based on the measured dark shading information (S70). In the operation of correcting an image by applying a dark shading value that fits for each region based on the measured dark shading information (S70), the gray scale of the active pixels (refer to AP in FIG. 3) of each region LUP, RUP, LDP, RDP, and CP may be corrected through the extracted black levels of the light-shielded pixels OBP1 to OBP5 of each region LUP, RUP, LDP, RDP, and CP. The correction of the gray scale of the active pixels (refer to AP in FIG. 3) of each region LUP, RUP, LDP, RDP, and CP may be the same as the image correction. The correcting the image (S70) may be performed through the ISP 300.

After correcting the image by applying a dark shading value that fits for each region based on the measured dark shading information (S70), the image is output (S80).

Referring back to FIGS. 3 and 5, in case of the effective pixel region 111 according to the embodiment, as described above, the first trench portion DTI may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In some implementations, because the light-shielded pixels (refer to OBP1 to OBP5 in FIG. 3) are disposed per region (refer to LUP, RUP, LDP, RDP, and CP) in the effective pixel region 111, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

Hereinafter, a pixel array of an image sensing device according to another embodiment will be described. With respect to the reference numerals or components which have been described referring to FIGS. 1 to 6, the redundant description thereof or the detailed description thereof will be omitted.

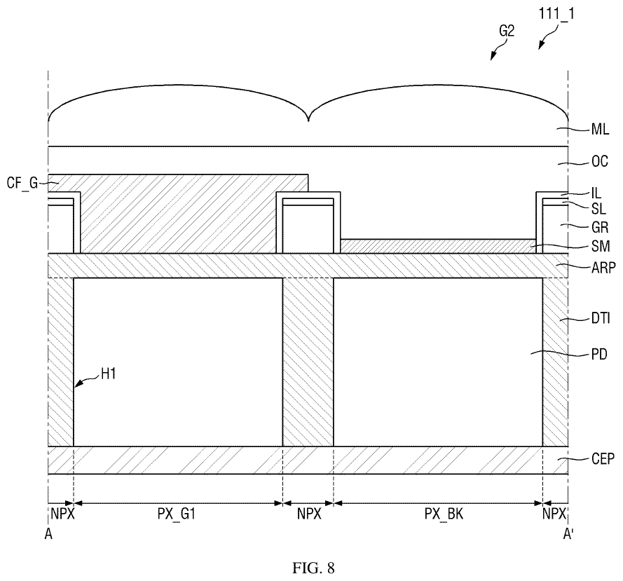

FIG. 8 is a cross-sectional view of a pixel array according to another embodiment.

Referring to FIG. 8, an effective pixel region 111_1 of a pixel array according to the present embodiment is different from the effective pixel region 111 according to FIG. 5 in that the light-shielded pixel region PX_BK does not include the black color filter CF_BK of FIG. 5.

In some implementations, the light-shielding layer SM may be directly disposed on an upper surface of the anti-reflection layer ARP.

In the present embodiment, the first trench portion DTI of the effective pixel region 111_1 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In some implementations, because the light-shielded pixels (refer to OBP1 to OBP5 in FIG. 3) are disposed per region (refer to LUP, RUP, LDP, RDP, and CP in FIG. 3) in the effective pixel region 111_1, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

In some implementations, by omitting the black color filter (CF_BK in FIG. 5), it is possible to reduce costs and save material for the black color filter.

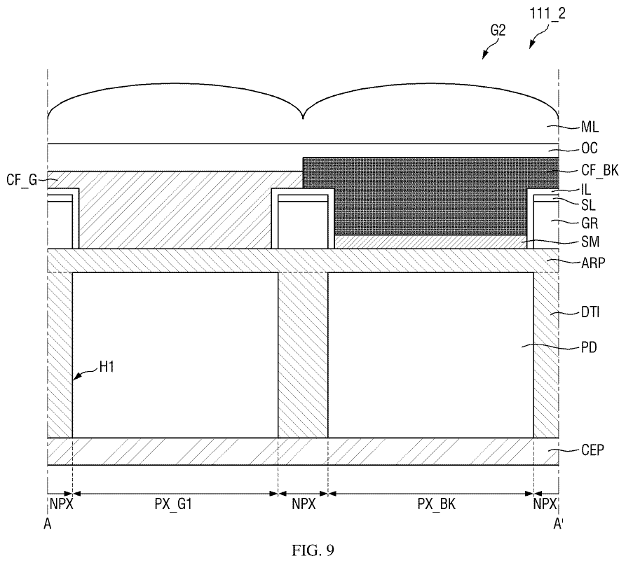

FIG. 9 is a cross-sectional view of a pixel array according to still another embodiment.

Referring to FIG. 9, an effective pixel region 111_2 of a pixel array according to the present embodiment is different from the effective pixel region 111 according to FIG. 5 in that the light-shielding layer SM is disposed below the black color filter CF_BK.

In some implementations, the light-shielding layer SM may be disposed between the anti-reflection layer ARP and the black color filter CF_BK. In the present embodiment, the first trench portion DTI of the effective pixel region 111_2 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_2, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

The description of other components, which have been provided referring to FIG. 5, will be omitted.

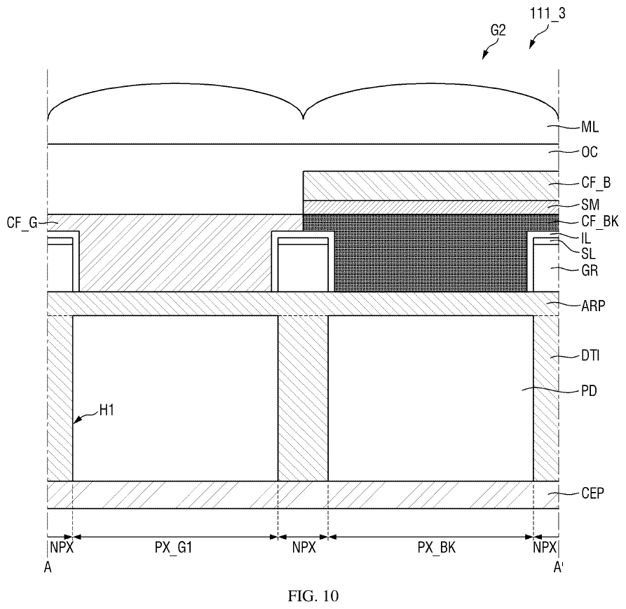

FIG. 10 is a cross-sectional view of a pixel array based on some implementations of the disclosed technology.

Referring to FIG. 10, an effective pixel region 111_3 of a pixel array according to the present embodiment is different from the effective pixel region 111 according to FIG. 5 in that the effective pixel region 111_3 further includes the blue color filter CF_B on the light-shielding layer SM.

The blue color filter CF_B may be disposed between the light-shielding layer SM and the planarization layer OC. In some embodiments, the blue color filter CF_B may be disposed between the light-shielding layer SM and the black color filter CF_BK, or between the black color filter CF_BK and the anti-reflection layer ARP. The incident light may include light in the red wavelength range, light in the green wavelength range, and light in the blue wavelength range. In general, the likelihood of the light in the long wavelength range to pass through the light-shielding layer SM may be higher, as compared to the light in the short wavelength range. In an embodiment, in order to filter primarily the light in the long wavelength range in the light-shielded pixel region PX_BK, the blue color filter CF_B may be further included on the light-shielding layer SM. Because of this, there is an effect that the amount of incident light introduced into the light-shielded pixel region PX_BK can dramatically decrease.

In the present embodiment, the first trench portion DTI of the effective pixel region 111_3 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In some implementations, because the light-shielded pixels (refer to OBP1 to OBP5 in FIG. 3) are disposed per region (refer to LUP, RUP, LDP, RDP, and CP in FIG. 3) in the effective pixel region 111_3, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

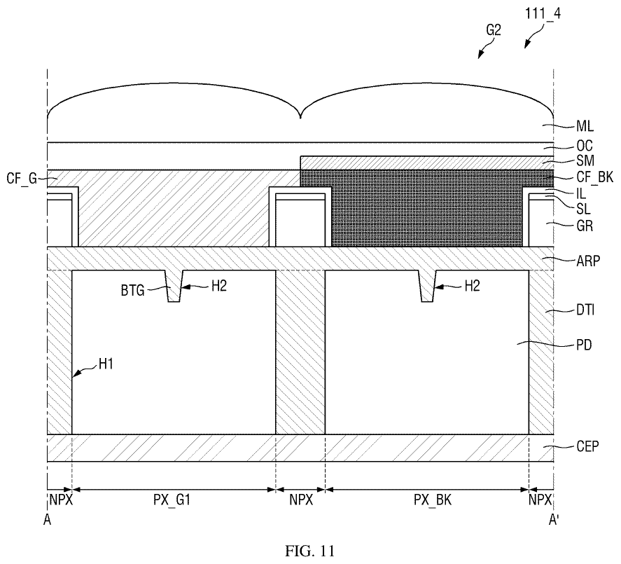

FIG. 11 is a cross-sectional view of a pixel array based on some implementations of the disclosed technology.

Referring to FIG. 11, the second groove H2 may be formed in the photodiode PD of the effective pixel region 111_4 of the pixel array according to the present embodiment, and the second groove H2 may be provided one or two in number, or three or more in number in the pixel regions PX_G1 and PX_BK. In the second groove H2, the second trench portion (BTG, Back side Trench Guide) may be disposed, and the second trench portion BTG may be provided one or two in number, or three or more in number in one pixel region PX_G1 and PX_BK. The first trench portion DTI and the second trench portion BTG may include the same material. For example, the first trench portion DTI and the second trench portion BTG may include an insulation material. For example, an example of the insulation material is hafnium oxide (HfO2), or silicon oxide (SiO2), but is not limited thereto. The second trench portion BTG may serve to scatter light incident from the light concentrating pattern ML. The first trench portion DTI and the second trench portion BTG may serve to increase a path of the light by totally reflecting the light to the photodiode PD or scattering the light, respectively. Because of this, the trench portion may serve to improve a quantum efficiency of the photodiode PD.

In the present embodiment, the first trench portion DTI of the effective pixel region 111_4 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_4, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

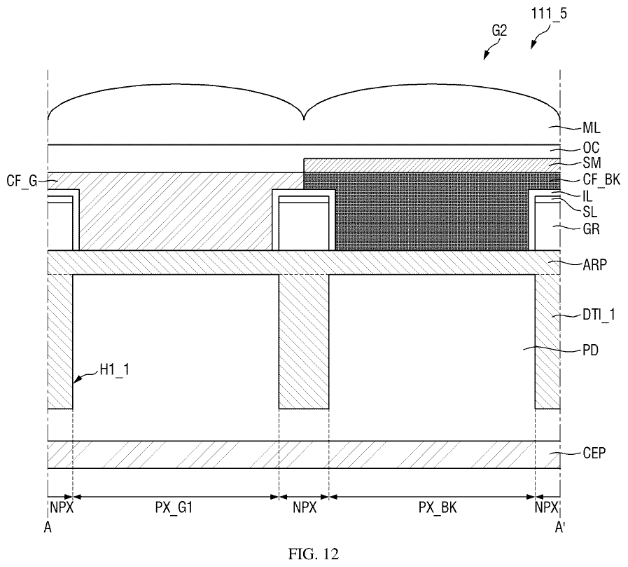

FIG. 12 is a cross-sectional view of a pixel array according to still another embodiment.

Referring to FIG. 12, an effective pixel region 111_5 of a pixel array according to the present embodiment is different from the effective pixel region 111 according to FIG. 5 in that a first groove H1_1 partially passes through the photodiode PD.

To describe it in more detail, the first groove H1_1 passes through the photodiode PD in a thickness direction from the upper surface of the photodiode PD, but the first groove H1_1 may not completely pass through the photodiode PD. The first trench portion DTI_1 is disposed in the first groove H1_1, and a bottom surface of the first trench portion DTI_1 may directly contact the photodiode PD.

In the present embodiment, the first trench portion DTI of the effective pixel region 111_5 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_5, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

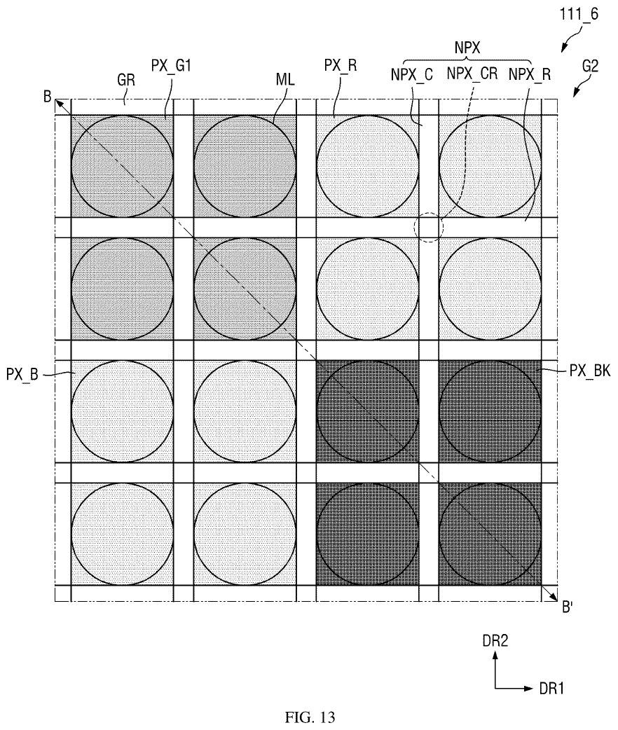

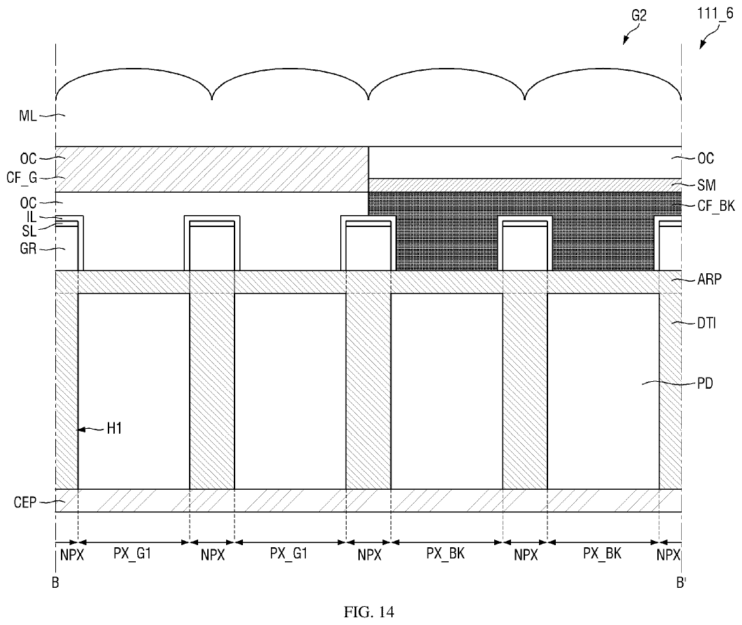

FIG. 13 is a plan view illustrating a second pixel group of an effective pixel region according to another embodiment. FIG. 14 is a cross-sectional view taken along section line B-B′ of FIG. 13.

Referring to FIGS. 13 and 14, each pixel in a pixel array 110_6 according to the present embodiment may be grouped into a plurality of groups. In FIGS. 13 and 14, a plan view and a cross-sectional view of a second pixel group G2 are illustrated as an example. For example, four pixels may be grouped and disposed. For example, as illustrated in FIG. 13, the first pixel, the second pixel, the third pixel, and the light-shielded pixel may be grouped by a four-pixel unit. For example, each pixel may be disposed in a two-by-two arrangement, but the embodiments of the present disclosure are not limited thereto.

For example, the grouped first pixels may be disposed two in number along a row direction (or a first direction DR1) and a column direction (or a second direction DR2), the grouped second pixels may be disposed two in number along the row direction (or the first direction DR1) and the column direction (or the second direction DR2), the grouped third pixels may be disposed two in number along the row direction (or the first direction DR1) and the column direction (or the second direction DR2), and the grouped light-shielded pixels may be disposed two in number along the row direction (or the first direction DR1) and the column direction (or the second direction DR2). The grouped first pixels, the grouped second pixels, the grouped third pixels, and the grouped light-shielded pixels may be disposed in a matrix form. That is, the grouped first pixels, the grouped second pixels, the grouped third pixels, and the grouped light-shielded pixels may be disposed along the row direction (or the first direction DR1) and the column direction (or the second direction DR2) in a matrix form.

The non-pixel region NPX may be formed between neighboring pixels. For example, the non-pixel region NPX may be disposed not only in boundaries between the grouped first pixels, the grouped second pixels, the grouped third pixels, and the grouped light-shielded pixels, but also in boundaries between the grouped first pixels, between the grouped second pixels, between the grouped third pixels, and between the grouped light-shielded pixels.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The first non-pixel region NPX_R may extend not only along a boundary between the grouped first pixels and the grouped third pixels and a boundary between the grouped second pixels and the grouped light-shielded pixels, but also along an internal boundary (a boundary extending along the first direction DR1) of each of the grouped first pixels, the grouped second pixels, the grouped third pixels, and the grouped light-shielded pixels.

The second non-pixel region NPX_C may extend not only along a boundary between the grouped first pixels and the grouped third pixels and a boundary between the grouped second pixels and the grouped light-shielded pixels, but also along an internal boundary (a boundary extending along the second direction DR2) of each of the grouped first pixels, the grouped second pixels, the grouped third pixels, and the grouped light-shielded pixels.

The light concentrating pattern ML may be provided in plurality. The plurality of light concentrating patterns ML may be disposed in each of the pixels. That is, the plurality of light concentrating patterns ML may be disposed in each of the grouped first pixels, may be disposed in each of the grouped second pixels, may be disposed in each of the grouped third pixels, and may be disposed in each of the grouped light-shielded pixels, but the embodiments of the present disclosure are not limited thereto. That is, the plurality of light concentrating patterns ML may be disposed in each pixel region of the grouped pixels. In FIG. 3, sixteen pixel regions are illustrated, and the light concentrating patterns ML may be sixteen in number.

The grid portion GR may be disposed throughout the first non-pixel region NPX_R and the second non-pixel region NPX_C of the non-pixel region NPX, and the grid portion GR may not be disposed over the third non-pixel region NPX_CR. However, the embodiments of the present disclosure are not limited thereto, and the grid portion GR may be disposed over the third non-pixel region NPX_CR.

In FIG. 13, for example, the second pixel group G2 is illustrated to include four light-shielded pixels which are grouped together, but the embodiments of the present disclosure are not limited thereto. For example, in the second pixel group G2, the light-shielded pixels may be disposed in only one to three regions among the four regions in which light-shielded pixels are disposed in FIG. 13, and the fourth pixel may be disposed in the remaining region thereof.

As illustrated in FIG. 14, the black color filter CF_BK may be integrally formed on two light-shielded pixels, and the light-shielding layer SM may be integrally formed on two light-shielded pixels, but the embodiments of the present disclosure are not limited thereto.

In the present embodiment, the first trench portion DTI of the effective pixel region 111_6 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_6, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

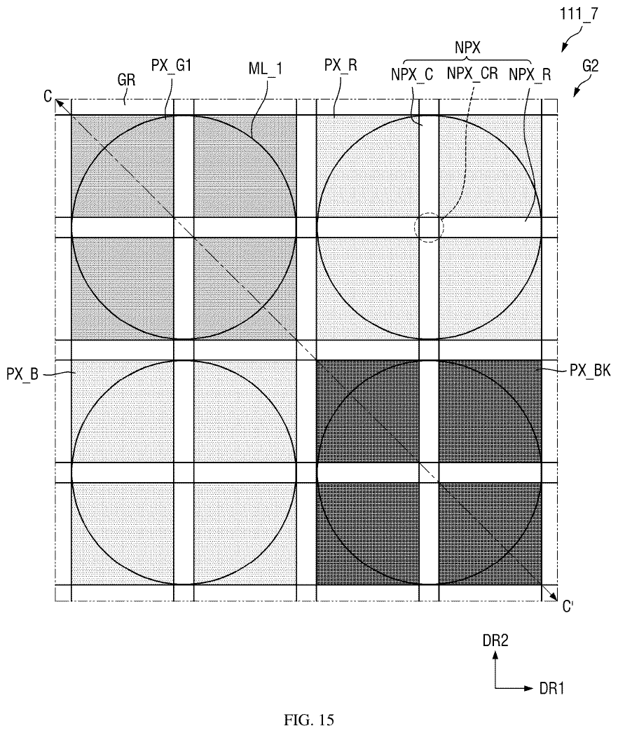

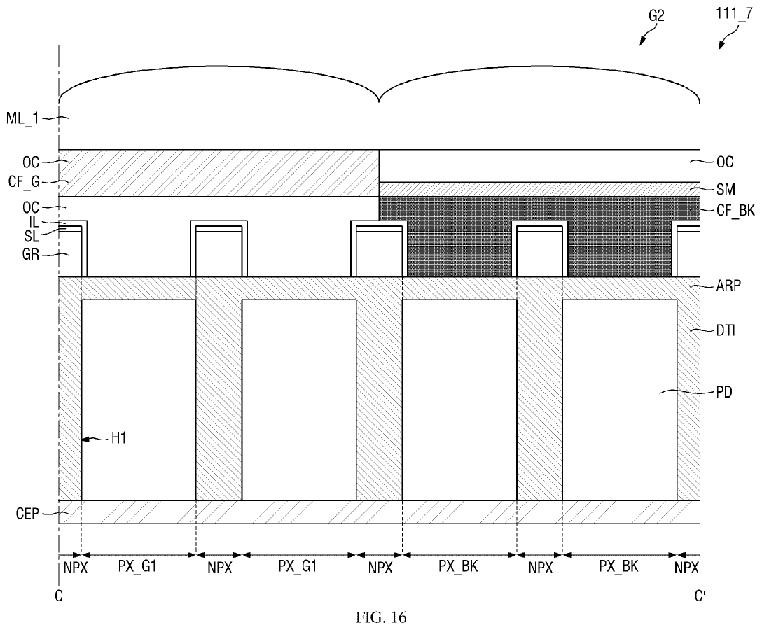

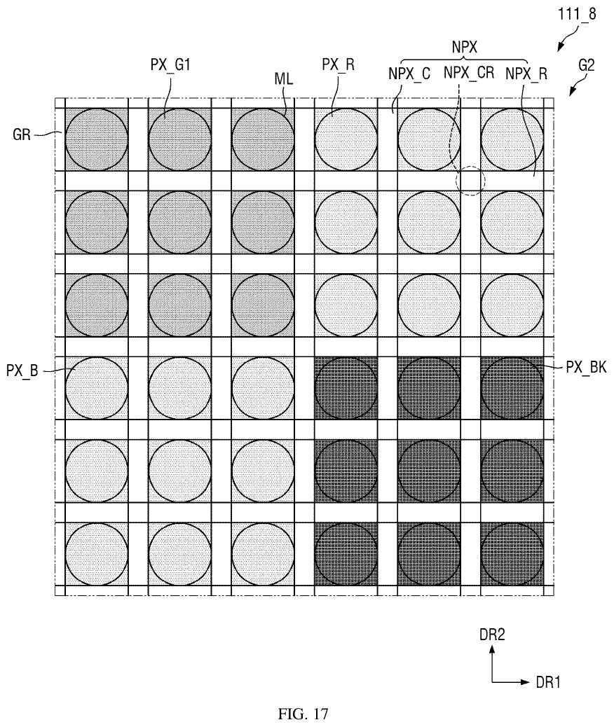

FIG. 15 is a plan view illustrating a second pixel group of an effective pixel region according to still another embodiment. FIG. 16 is a cross-sectional view taken along section line C-C′ of FIG. 15.

Referring to FIGS. 15 and 16, an effective pixel region 111_7 of a pixel array according to the present embodiment is different from the effective pixel region 111_6 according to FIGS. 13 and 14 in that a light concentrating pattern ML_1 of the effective pixel region 111_7 is disposed in correspondence with the grouped pixels.

To describe it in more detail, one light concentrating pattern ML_1 is disposed on four first pixels, one light concentrating pattern ML_1 is disposed on four second pixels, one light concentrating pattern ML_1 is disposed on four third pixels, and one light concentrating pattern ML_1 is disposed on four light-shielded pixels.

The description of other components, which have been provided referring to FIGS. 13 and 14, will be omitted.

In the present embodiment, the first trench portion DTI of the effective pixel region 111_7 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_7, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

FIG. 17 is a plan view illustrating a second pixel group of an effective pixel region according to still another embodiment.

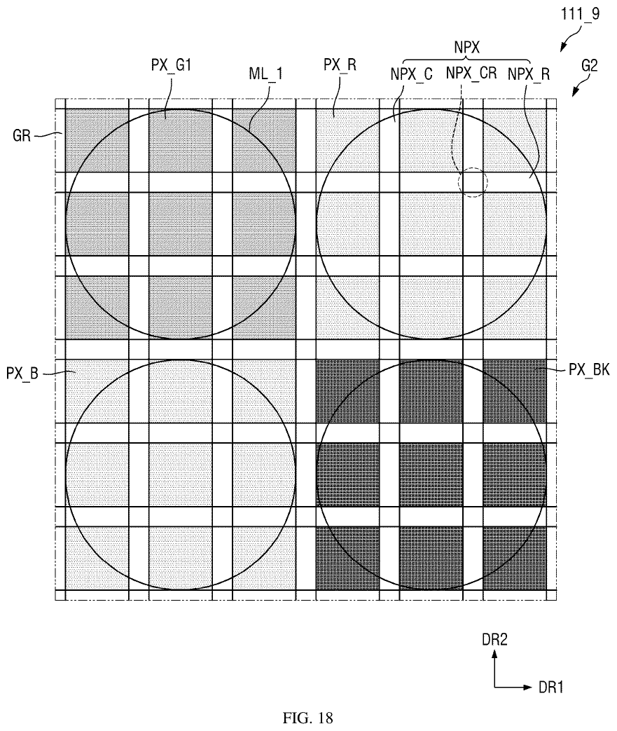

Referring to FIG. 17, each pixel in a pixel array 110_8 according to the present embodiment may be grouped into a plurality of groups. For example, nine pixels may be grouped and disposed. For example, as illustrated in FIG. 18, the first pixel, the second pixel, the third pixel, and the light-shielded pixel may be grouped by a nine-pixel unit. For example, each pixel may be disposed in a three-by-three arrangement, but the embodiments of the present disclosure are not limited thereto. In some embodiments, a four-by-four arrangement may be applied. For example, the grouped first pixels may be disposed three in number along a row direction (or a first direction DR1) and a column direction (or a second direction DR2), the grouped second pixels may be disposed three in number along the row direction (or the first direction DR1) and the column direction (or the second direction DR2), the grouped third pixels may be disposed three in number along the row direction (or the first direction DR1) and the column direction (or the second direction DR2), and the grouped light-shielded pixels may be disposed three in number along the row direction (or the first direction DR1) and the column direction (or the second direction DR2). The grouped first pixels, the grouped second pixels, the grouped third pixels, and the grouped light-shielded pixels may be disposed in a matrix form. That is, the grouped first pixels, the grouped second pixels, the grouped third pixels, and the grouped light-shielded pixels may be disposed along the row direction (or the first direction DR1) and the column direction (or the second direction DR2) in a matrix form.

The non-pixel region NPX may be formed between neighboring pixels. For example, the non-pixel region NPX may be disposed not only in boundaries between the grouped first pixels, the grouped second pixels, the grouped third pixels, and the grouped light-shielded pixels, but also in boundaries between the grouped first pixels, between the grouped second pixels, between the grouped third pixels, and between the grouped light-shielded pixels.

For example, the non-pixel region NPX may include a first non-pixel region NPX_R extending along the row direction (or the first direction DR1), a second non-pixel region NPX_C extending along the column direction (or the second direction DR2), and a third non-pixel region NPX_CR extending in a boundary between the first non-pixel region NPX_R and the second non-pixel region NPX_C.

The first non-pixel region NPX_R may extend not only along a boundary between the grouped first pixels and the grouped third pixels and a boundary between the grouped second pixels and the grouped light-shielded pixels, but also along an internal boundary (a boundary extending along the first direction DR1) of each of the grouped first pixels, the grouped second pixels, the grouped third pixels, and the grouped light-shielded pixels.

The second non-pixel region NPX_C may extend not only along a boundary between the grouped first pixels and the grouped third pixels and a boundary between the grouped second pixels and the grouped light-shielded pixels, but also along an internal boundary (a boundary extending along the second direction DR2) of each of the grouped first pixels, the grouped second pixels, the grouped third pixels, and the grouped light-shielded pixels.

In the present embodiment, the first trench portion DTI of the effective pixel region 111_8 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_8, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

In FIG. 17, for example, the second pixel group G2 is illustrated to include nine light-shielded pixels which are grouped together, but the embodiments of the present disclosure are not limited thereto. For example, in the second pixel group G2, the light-shielded pixels may be disposed in only one to eight regions among the nine regions in which light-shielded pixels are disposed in FIG. 17, and the fourth pixel may be disposed in the remaining region thereof.

FIG. 18 is a plan view illustrating a second pixel group of an effective pixel region according to still another embodiment.

Referring to FIG. 18, an effective pixel region 111_9 of a pixel array according to the present embodiment is different from the effective pixel region 111_8 according to FIG. 17 in that the light concentrating pattern ML_1 of the effective pixel region 111_9 is disposed in correspondence with the grouped pixels.

To describe it in more detail, one light concentrating pattern ML_1 is disposed on nine first pixels, one light concentrating pattern ML_1 is disposed on nine second pixels, one light concentrating pattern ML_1 is disposed on nine third pixels, and one light concentrating pattern ML_1 is disposed on nine light-shielded pixels.

In some embodiments, a four-by-four or higher arrangement may be applied, and one light concentrating pattern ML_1 may be disposed on the pixels disposed in the four-by-four arrangement or the higher arrangement.

In the present embodiment, the first trench portion DTI of the effective pixel region 111_9 may be disposed by completely passing through a layer including the photodiode PD from the upper surface to the bottom surface thereof in a thickness direction. For example, the first trench portion DTI may prevent the light incident into the first pixel region PX_G1 from moving to the light-shielded pixel region PX_BK. Therefore, by preventing the light from entering from a pixel region neighboring to the light-shielded pixel region PX_BK, the reliability of the light-shielded pixel (refer to OBP1 to OBP5 in FIG. 3) may be improved.

In addition, because the light-shielded pixels (refer to OBP1 to OBP5 in FIG. 3) are disposed per region (refer to LUP, RUP, LDP, RDP, and CP in FIG. 3) in the effective pixel region 111_9, and the black level and the degree of the dark shading per region (LUP, RUP, LDP, RDP, and CP) can be determined precisely, there is an effect that the gray scale (or image pixel signal) of the active pixels (refer to AP in FIG. 3) per region (LUP, RUP, LDP, RDP, and CP) can be precisely corrected or compensated.

The image sensing device according to the various embodiments of the present disclosure may be described as below.

One embodiment is an imaging device, including: an image sensing device including: an effective pixel region in which a first pixel group including active pixels configured to convert incident light into an electric signal to generate image pixel signals; and a second pixel group including the active pixels and light-shielded pixels into which introduction of the incident light is blocked are disposed; and an image signal processor configured to control the image sensing device.

The imaging device may further include: a dummy pixel region configured to surround the effective pixel region and comprising dummy pixels.

The active pixels of the second pixel group may include a first pixel, a second pixel, and a third pixel.

The active pixels of the first pixel group may include the first pixel, the second pixel, the third pixel, and the fourth pixel, and the first pixel and the fourth pixel may be pixels having a same color.

The light-shielded pixel may include a light-shielded pixel region and a non-pixel region around the light-shielded pixel region, and comprises a circuitry, a photodiode disposed on the circuitry in the light-shielded pixel region, and a first trench portion formed in a first groove of the photodiode.

The first groove may be configured to completely pass through the photodiode.

The light-shielded pixel may further include an anti-reflection layer on the photodiode and the first trench portion.

The light-shielded pixel may further include a light-shielding layer on the anti-reflection layer.

The light-shielding layer may include a reflective electrode.

The light-shielded pixel may further include a light concentrating pattern on the light-shielding layer.

The light-shielded pixel may further include a planarization layer between the light-shielding layer and the light concentrating pattern.

The light-shielded pixel may further include a blue color filter on the light-shielding layer.

The light-shielded pixel may further include a grid portion between the anti-reflection layer and the light-shielding layer in the non-pixel region.

The light-shielded pixel may further include a black color filter on the anti-reflection layer.

The black color filter may have a stacked-layer structure of a red color filter, a green color filter, and a blue color filter.

The light-shielded pixel may further include a second trench portion formed in a second groove of the photodiode in the light-shielded pixel region, and a depth of the second groove may be lower than a depth of the first groove.

The image signal processor may be configured to divide position pixel groups into a first position pixel group disposed at a first position of the effective pixel region, and a second position pixel group disposed at a second position of the effective pixel region, and each of the first position pixel group and the second position pixel group may include the first pixel group and the second pixel group.

The image signal processor may be configured to extract a black level of each of the light-shielded pixel of the second pixel group of the first position pixel group, and the light-shielded pixel of the second pixel group of the second position pixel group.

The image signal processor may be configured to compensate a black level of a rest of the active pixels of the first position pixel group through the extracted black level of the light-shielded pixel of the second pixel group of the first position pixel group, and to compensate a black level of a rest of the active pixels of the second position pixel group through the extracted black level of the light-shielded pixel of the second pixel group of the second position pixel group.

The image signal processor may be configured to replace an image pixel signal of the light-shielded pixel of the second pixel group of the first position pixel group with a neighboring image pixel signal of the active pixel of the first pixel group or the second pixel group of the first position pixel group to transmit the replaced image pixel signal to a host device, and to replace an image pixel signal of the light-shielded pixel of the second pixel group of the second position pixel group with a neighboring image pixel signal of the active pixel of the first pixel group or the second pixel group of the second position pixel group to transmit the replaced image pixel signal to a host device.

The image signal processor may be configured to generate dark shading information based on the extracted black level of each of the light-shielded pixel of the second pixel group of the first position pixel group and the light-shielded pixel of the second pixel group of the second position pixel group.

The image signal processor may be configured to correct image pixel signals of the active pixels of the first position pixel group and the active pixels of the second position pixel group based on the generated dark shading information.

Another embodiment is an imaging sensing device, including: an effective pixel region in which a first pixel group including active pixels configured to convert incident light into an electric signal to generate image pixel signals; and a second pixel group including the active pixels and light-shielded pixels into which introduction of the incident light is blocked are disposed.

The imaging sensing device may further include: a dummy pixel region configured to surround the effective pixel region and including dummy pixels.

The active pixels of the second pixel group may include a first pixel, a second pixel, and a third pixel, the active pixels of the first pixel group may include the first pixel, the second pixel, the third pixel, and the fourth pixel, and the first pixel and the fourth pixel may be pixels having a same color.

The light-shielded pixel may include a light-shielded pixel region and a non-pixel region around the light-shielded pixel region, and may include a circuitry, a photodiode disposed on the circuitry in the light-shielded pixel region, and a first trench portion formed in a first groove of the photodiode.

The first groove may be configured to completely pass through the photodiode.

The light-shielded pixel may further include an anti-reflection layer on the photodiode and the first trench portion; and a light-shielding layer on the anti-reflection layer.

The light-shielding layer may include a reflective electrode.

The light-shielded pixel may further include a light concentrating pattern on the light-shielding layer, and a planarization layer between the light-shielding layer and the light concentrating pattern.

Only a few implementations and examples are described and other implementations, enhancements and variations can be made based on what is described and illustrated in this patent document.

I/we claim:

1. An imaging device, comprising:
an image sensing device including a pixel array that includes an image pixel region; and
an image signal processor in communication with the image sensing device and configured to control the image sensing device,
wherein the image pixel region includes 1) a first pixel group comprising first active pixels and 2) a second pixel group comprising second active pixels and light-shielded pixels into which introduction of incident light is blocked, each of the first active pixels and the second active pixels configured to convert incident light into an electric signal to generate image pixel signals.

2. The imaging device of claim 1, further comprising:
a dummy pixel region disposed adjacent and separately from the image pixel region and comprising dummy pixels configured to produce dummy pixel signals different from the image pixel signals.

3. The imaging device of claim 1,
wherein the second active pixels of the second pixel group comprise a first pixel corresponding to a first color, a second pixel corresponding to a second color, and a third pixel corresponding to a third color.

4. The imaging device of claim 3,
wherein the first active pixels of the first pixel group comprise another first pixel corresponding to the first color, another second pixel corresponding to the second color, another third pixel, and a fourth pixel corresponding to the first color.

5. The imaging device of claim 1,
wherein the light-shielded pixels include a light-shielded pixel that comprises a light-shielded pixel region and a non-pixel region adjacent to the light-shielded pixel region, the light-shielded pixel further comprising a circuitry, a photodetector disposed on the circuitry in the light-shielded pixel region, and a first trench portion formed in a first groove of a layer including the photodetector.

6. The imaging device of claim 5,
wherein the first groove is configured to completely pass through a layer including the photodetector.

7. The imaging device of claim 5,
wherein the light-shielded pixel further comprises an anti-reflection layer on the photodetector and the first trench portion; and a light-shielding layer on the anti-reflection layer.

8. The imaging device of claim 7,
wherein the light-shielding layer comprises a reflective electrode.

9. The imaging device of claim 7,
wherein the light-shielded pixel further comprises a light concentrating pattern on the light-shielding layer.

10. The imaging device of claim 9,
wherein the light-shielded pixel further comprises a planarization layer between the light-shielding layer and the light concentrating pattern.

11. The imaging device of claim 7,
wherein the light-shielded pixel further comprises a blue color filter on the light-shielding layer.

12. The imaging device of claim 7,
wherein the light-shielded pixel further comprises a black color filter on the anti-reflection layer.

13. The imaging device of claim 12,
wherein the black color filter has a stacked-layer structure of a red color filter, a green color filter, and a blue color filter.

14. The imaging device of claim 5,
wherein the light-shielded pixel further comprises a second trench portion formed in a second groove of a layer including the photodetector in the light-shielded pixel region, and
wherein a depth of the second groove is lower than a depth of the first groove.

15. The imaging device of claim 1,
wherein the image signal processor is configured to divide position pixel groups into a first position pixel group disposed at a first position of the image pixel region, and a second position pixel group disposed at a second position of the image pixel region, and
wherein the first position pixel group includes the first pixel group and the second pixel group, and
wherein the second position pixel group comprises an additional first pixel group and an additional second pixel group.

16. The imaging device of claim 15,
wherein the image signal processor is configured to extract a black level of each of a light-shielded pixel of the second pixel group of the first position pixel group, and a light-shielded pixel of the additional second pixel group of the second position pixel group.

17. The imaging device of claim 16,
wherein the image signal processor is configured to compensate a black level of the first active pixels of the first position pixel group based on the extracted black level of a light-shielded pixel of the second pixel group of the first position pixel group, and to compensate a black level of active pixels of the second position pixel group based on the extracted black level of a light-shielded pixel of the additional second pixel group of the second position pixel group, and
wherein the image signal processor is configured to replace an image pixel signal of the light-shielded pixel of the second pixel group of the first position pixel group with a neighboring image pixel signal of a first active pixel of the first pixel group or a second active pixel of the second pixel group of the first position pixel group to transmit the replaced image pixel signal to a host device, and to replace an image pixel signal of the light-shielded pixel of the additional second pixel group of the second position pixel group with a neighboring image pixel signal of an active pixel of the additional first pixel group or the additional second pixel group of the second position pixel group to transmit the replaced image pixel signal to a host device.

18. The imaging device of claim 16,
wherein the image signal processor is configured to generate dark shading information based on the extracted black level of each of the light-shielded pixel of the second pixel group of the first position pixel group and a light-shielded pixel of the additional second pixel group of the second position pixel group, and
wherein the image signal processor is configured to correct image pixel signals of the first active pixels and the second active pixels of the first position pixel group and active pixels of the second position pixel group based on the generated dark shading information.

19. An imaging sensing device, comprising:
an image pixel region including a first pixel group comprising first active pixels and a second pixel group comprising second active pixels, each of the first active pixels and the second active pixels configured to convert incident light into an electric signal to generate image pixel signals; wherein the second pixel group further comprising light-shielded pixels into which introduction of the incident light is blocked.

20. The imaging sensing device of claim 19, further comprising:
a dummy pixel region disposed adjacent and separately from the image pixel region and comprising dummy pixels configured to produce dummy pixel signals different from the image pixel signals.
